(19) United States
(12) Patent Application Publication
(10) Pub. No.: US 2026/0328491 A1
(43) Pub. Date: Oct. 22, 2026

(54) HEAT TRANSFER ELEMENT

(71) Applicant: Fujikura Ltd., Tokyo (JP)

(72) Inventors: Harutoshi Hagino, Sakura-shi (JP); Yoji Kawahara, Sakura-shi (JP); Long Thanh Phan, Sakura-shi (JP); Takeshi Koshio, Sakura-shi (JP); Yuji Saito, Sakura-shi (JP)

(73) Assignee: Fujikura Ltd., Tokyo (JP)

(21) Appl. No.: 19/184,852

(22) Filed: Apr. 21, 2025

(51) Int. Cl. F28D 15/04

(52) U.S. Cl. CPC F28D 15/04

(57) ABSTRACT

A heat transfer element includes: a heat exchange portion; and a vapor chamber connected to an end of the heat exchange portion and that has a contact surface that contacts a heat generating body. The vapor chamber includes: a first container that communicates with an inner space of the heat exchange portion and forms a storage chamber in which a working fluid is stored; and a wick disposed in the storage chamber and configured to retain the working fluid. The heat exchange portion includes a second container that forms the inner space. The second container includes a container protruding portion that protrudes into the storage chamber toward the wick. The container protruding portion is formed on a partial periphery of the second container along a peripheral direction around a central axis of the second container.

### TECHNICAL FIELD

The present invention relates to a heat transfer element.

### BACKGROUND

Patent Document 1 discloses a cooler including a heat receiving portion on which a heat generating body such as an electronic component is mounted, a heat pipe that is joined to the heat receiving portion and in which a working fluid is accommodated, and a cooling fin provided on a surface of the heat pipe in order to cool the heat generating body. In this cooler, in a case where the heat of the heat generating body is transferred to the heat pipe through the heat receiving portion and the working fluid in the heat pipe is heated to a saturation temperature or higher, the working fluid is vaporized. The vaporized working fluid is condensed by radiating heat to the outside through the heat pipe and the cooling fin.

### PATENT LITERATURE

Patent Document 1: Japanese Unexamined Patent Application, First Publication No. 2004-44966

By the way, a storage chamber which communicates with an inner space of a heat exchange portion (a heat pipe or the like) and in which a working fluid is stored may be provided in the heat receiving portion. Further, in a case where the storage chamber is provided with a wick capable of capturing and holding the working fluid by a capillary force, the working fluid condensed in the heat exchange portion may be smoothly recovered by the wick in the storage chamber.

However, due to a surface tension of the working fluid or the like, the working fluid is transmitted from an inner peripheral surface of the heat exchange portion to an inner peripheral surface of the storage chamber, and the working fluid may not be smoothly recovered by the wick in the storage chamber.

### SUMMARY

One or more embodiments of the present invention provide a heat transfer element capable of smoothly recovering a working fluid condensed in a heat exchange portion with a wick in a storage chamber.

According to Embodiment 1 of the present invention, there is provided a heat transfer element including: a heat exchange portion that extends in a first direction; and a vapor chamber that is connected to a first end portion of the heat exchange portion and has a contact surface that comes into contact with a heat generating body, in which the vapor chamber includes a first container that communicates with an inner space of the heat exchange portion and forms a storage chamber in which a working fluid is stored, and a first wick that is disposed in the storage chamber and is configured to retain the working fluid, the heat exchange portion includes a second container that forms the inner space, and the second container includes a container protruding portion that protrudes toward the first wick in the storage chamber in a part of a peripheral direction around a central axis of the second container.

Embodiment 2 of the present invention is the heat transfer element according to Embodiment 1, in which a tip end portion of the container protruding portion is in contact with the first wick.

Embodiment 3 of the present invention is the heat transfer element according to Embodiment 1 or 2, in which the second container includes a plurality of container protruding portions including the container protruding portion, and the plurality of container protruding portions are provided at intervals in the peripheral direction of the second container.

According to Embodiment 4 of the present invention, there is provided a heat transfer element including: a heat exchange portion that extends in a first direction; and a vapor chamber that is connected to a first end portion of the heat exchange portion and has a contact surface that comes into contact with a heat generating body, in which the vapor chamber includes a first container that communicates with an inner space of the heat exchange portion and forms a storage chamber in which a working fluid is stored, and a first wick that is disposed in the storage chamber and is configured to retain the working fluid, the heat exchange portion includes a second container that forms the inner space, and a second wick that is provided in the inner space and is configured to retain the working fluid, and the second wick includes a wick protruding portion that protrudes toward the first wick in the storage chamber in a part of a peripheral direction around a central axis of the second container.

Embodiment 5 of the present invention is the heat transfer element according to Embodiment 4, in which a tip end portion of the wick protruding portion is in contact with the first wick.

Embodiment 6 of the present invention is the heat transfer element according to Embodiment 4 or 5, in which the second wick is provided in a part of an inner peripheral surface of the second container in the peripheral direction, and extends in the first direction.

Embodiment 7 of the present invention is the heat transfer element according to Embodiment 6, in which the heat exchange portion includes a plurality of second wicks including the second wick, and the plurality of second wicks are provided on the inner peripheral surface of the second container at intervals in the peripheral direction.

Embodiment 8 of the present invention is the heat transfer element according to Embodiment 4 or 5, in which the second wick is provided over an entire periphery of the second container in the peripheral direction on an inner peripheral surface of the second container, and extends in the first direction.

Embodiment 9 of the present invention is the heat transfer element according to any one of Embodiments 4 to 8, in which the second wick includes a plurality of wick protruding portions including the wick protruding portion, and the plurality of wick protruding portions are provided at intervals in the peripheral direction in an inner peripheral surface of the second container.

Embodiment 10 of the present invention is the heat transfer element according to any one of Embodiments 1 to 9, further including a cooling fin joined to an outer peripheral surface of the heat exchange portion.

According to the above-described embodiments of the present invention, the working fluid condensed in the heat exchange portion can be smoothly recovered by the wick in the storage chamber.

### BRIEF DESCRIPTION OF THE DRAWINGS

FIG. 1 is a cross-sectional view of a heat transfer element according to first embodiments.

FIG. 2 is a cross-sectional view of a heat exchange portion of the heat transfer element according to the first embodiments when viewed from a first direction.

FIG. 3 is a view of the heat exchange portion in FIG. 2 when viewed from a second direction.

FIG. 4 is a cross-sectional view of the heat transfer element according to a modification example of the first embodiments.

FIG. 5 is a cross-sectional view showing a heat transfer element according to second embodiments.

FIG. 6 is a cross-sectional view of a heat exchange portion of the heat transfer element according to the second embodiments when viewed from a first direction.

FIG. 7 is a view of the heat exchange portion in FIG. 6 when viewed from a second direction.

FIG. 8 is a cross-sectional view of a heat exchange portion according to a modification example of the second embodiments when viewed from the first direction.

FIG. 9 is a view showing examination results of the embodiments.

### DETAILED DESCRIPTION

Hereinafter, a heat transfer element according to one or more embodiments will be described with reference to the drawings.

### First Embodiments

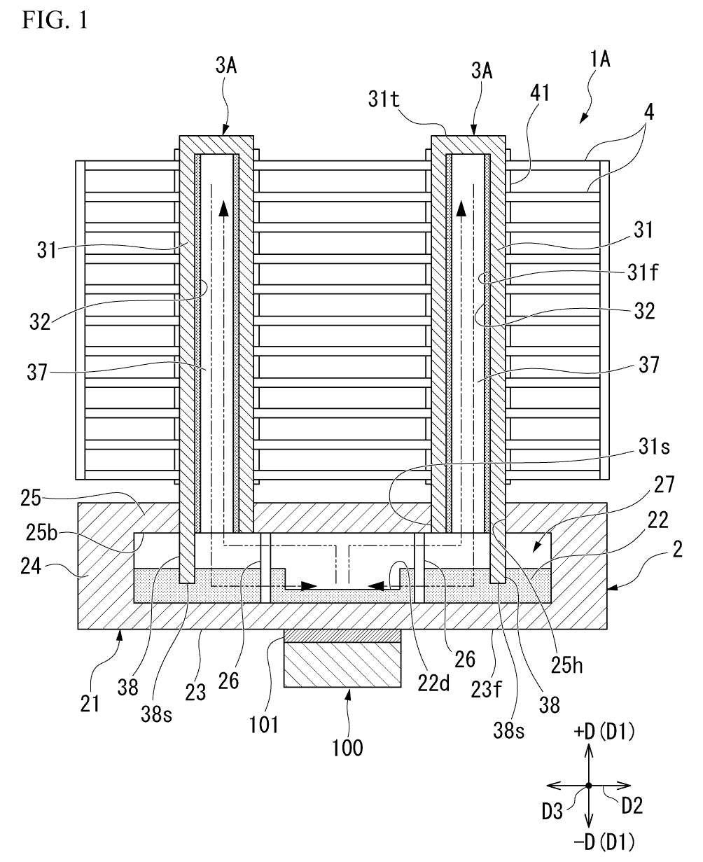

As shown in FIG. 1, a heat transfer element lA includes a vapor chamber 2, a plurality of heat exchange portions 3A, and a plurality of cooling fins 4. The number of heat exchange portions 3A may be one. In addition, the heat transfer element lA may not include the cooling fins 4. The heat exchange portions 3A of one or more embodiments are heat pipes. However, a component other than the heat pipes (for example, a flat-shaped vapor chamber) may be used as each of the heat exchange portions 3A.

### Definition of Direction

In the present specification, a direction in which the heat exchange portion 3A extends is referred to as a first direction D1. In the first direction D1, a direction from the vapor chamber 2 to the heat exchange portion 3 is referred to as a +D 1 direction, and a direction from the heat exchange portion 3 to the vapor chamber 2 is referred to as a -D1 direction.

A direction orthogonal to the first direction D1 is referred to as a second direction D2. A direction orthogonal to both the first direction D1 and the second direction D2 is referred to as a third direction D3. In addition, in each heat exchange portion 3A, a direction around a central axis of the heat exchange portion 3A is referred to as a peripheral direction.

The vapor chamber 2 includes a first container 21 and a first wick 22.

The first container 21 is formed from, for example, copper, a copper alloy, aluminum, or an aluminum alloy. The first container 21 may be formed from a material other than those described above.

The first container 21 has a hollow box shape. The first container 21 is formed in a flat shape in which outer dimensions in the second direction D2 and the third direction D3 are larger than a thickness dimension in the first direction D1. The first container 21 integrally includes a bottom wall portion 23, an outer peripheral wall portion 24, and an upper wall portion 25. The bottom wall portion 23 is disposed in the -D direction (downward in FIG. 1) with respect to the upper wall portion 25. The bottom wall portion 23 has, for example, a rectangular shape when viewed in the first direction D1. The bottom wall portion 23 extends along a plane including the second direction D2 and the third direction D3. The bottom wall portion 23 has a contact surface 23f facing the -D direction. A heat generating body 100 such as various semiconductor elements including a CPU or a GPU is in contact with the contact surface 23f through thermal conductive grease 101 including a material having high thermal conductivity.

The outer peripheral wall portion 24 rises from an outer peripheral portion of the bottom wall portion 23 in the +D direction. The upper wall portion 25 is disposed on the +D 1 direction side of the bottom wall portion 23, and the upper wall portion 25 and the bottom wall portion 23 are disposed to be spaced from each other. The upper wall portion 25 has, for example, a rectangular shape when viewed in the first direction D1. The upper wall portion 25 extends along a plane including the second direction D2 and the third direction D3. The upper wall portion 25 is provided to cover an inner space of the outer peripheral wall portion 24 from the +D direction side.

A plurality of reinforcing columns 26 are provided between the bottom wall portion 23 and the upper wall portion 25. The plurality of reinforcing columns 26 are disposed at intervals in the second direction D2 and the third direction D3. Each of the reinforcing columns 26 extends in the first direction D1 and connects the bottom wall portion 23 and the upper wall portion 25 to each other.

In such a first container 21, a storage chamber 27 surrounded by the bottom wall portion 23, the outer peripheral wall portion 24, and the upper wall portion 25 is formed. The storage chamber 27 extends along the second direction D2 and the third direction D3. A working fluid is stored in the storage chamber 27.

The working fluid is a heat transfer medium consisting of a known phase change material, and undergoes a phase change between a liquid phase and a gas phase in the heat transfer element lA. For example, water (pure water), alcohol, ammonia, or the like can be used as the working fluid. In addition, the working fluid will be described as "liquid" in a case of the liquid phase and "vapor" in a case of the gas phase. In addition, in a case where the liquid phase and the gas phase are not particularly distinguished, the liquid phase and the gas phase may be described as a working fluid. In addition, the working fluid is not shown.

The first wick 22 is provided in the storage chamber 27. The first wick 22 is disposed along the bottom wall portion 23 in the storage chamber 27. The first wick 22 has a predetermined thickness in the first direction D1. The first wick 22 is disposed to be spaced apart from the upper wall portion 25 on the -D direction side. The first wick 22 is formed from a powder wick consisting of a sintered porous body of a metal powder such as copper, a wire wick which is a braided body consisting of a plurality of metal wires such as copper, and the like. The first wick 22 is capable of capturing and retaining the working fluid in the first container 21 by a capillary force thereof. A recessed portion 22d that is recessed in the -D direction is formed in the central portion of the first wick 22. A part of the working fluid retained in the first wick 22 may be exposed in the recessed portion 22d.

The plurality of heat exchange portions 3A are disposed at intervals in the second direction D2 and the third direction D3. In each of the heat exchange portions 3A, a base end portion in the -D direction is joined to the vapor chamber 2. The heat exchange portion 3A protrudes and extends from the upper wall portion 25 of the vapor chamber 2 toward the +D direction.

The heat exchange portion 3A includes a cylindrical second container 31 and a second wick 32. The second container 31 is formed from, for example, copper, a copper alloy, aluminum, or an aluminum alloy. The second container 31 may be formed from a material other than those described above.

The second container 31 has a hollow cylindrical shape extending in the first direction D1, and a first end portion 31s on the -D direction side is an open end and a second end portion 31t on the +D direction side is a closed end. A plurality of the second containers 31 are provided at intervals in the second direction D2 and the third direction D3. In one or more embodiments, two second containers 31 are provided at intervals in the second direction D2. Two second containers 31 are provided at intervals in the third direction D3. That is, a total of four second containers 31 are provided. It is noted that the number of the second containers 31 may be one, two, or three, or may be five or more.

An inner space 37 extending in the first direction D1 is formed in the second container 31. The first end portion 31sof the second container 31 is inserted into a through-hole 25h formed in the upper wall portion 25 of the vapor chamber 2 and is joined to the upper wall portion 25 by brazing, welding, adhesion, or the like. Accordingly, the inner space 37 in the second container 31 communicates with the storage chamber 27 in the vapor chamber 2.

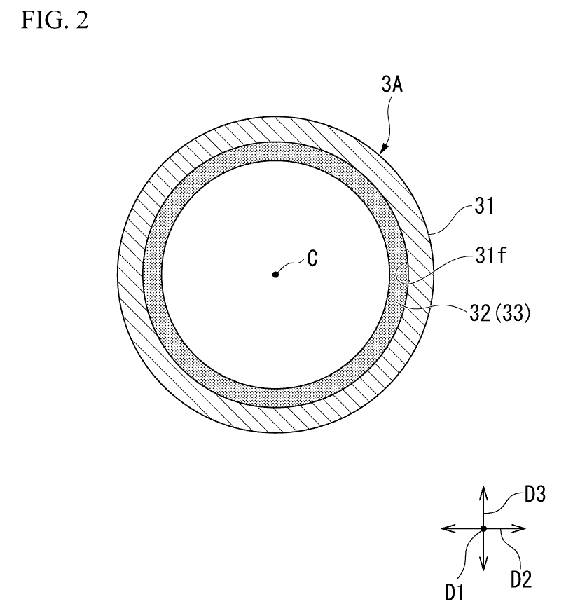

FIG. 2 is a cross-sectional view of the heat exchange portion 3A. As shown in FIGS. 1 and 2, the second wick 32 is provided in the second container 31. The second wick 32 is disposed along an inner peripheral surface 31 f of the second container 31 in the second container 31. As shown in FIG. 2, the second wick 32 is provided on the inner peripheral surface 31 f of the second container 31 over the entire periphery in the peripheral direction around the central axis C of the second container 31. The second wick 32 extends in the first direction D1 along the inner peripheral surface 31 f of the second container 31.

The second wick 32 is formed from a powder wick consisting of a sintered porous body of a metal powder such as copper, a wire wick which is a braided body consisting of a plurality of metal wires such as copper, and the like. The second wick 32 is capable of capturing and retaining the working fluid condensed in the second container 31 by a capillary force in the second container 31. In one or more embodiments, the second wick 32 is not an essential configuration, and the second wick 32 may be omitted.

As shown in FIG. 1, the cooling fins 4 are joined to an outer peripheral surface of the heat exchange portion 3A. The cooling fins 4 are formed in a plate shape extending along the second direction D2 and the third direction D3. The plurality of cooling fins 4 are provided at intervals in the first direction D1. A cylindrical sleeve 41 extending in the first direction D1 is provided on the outer peripheral surface of the heat exchange portion 3A. Each of the cooling fins 4 is joined to the second container 31 of the heat exchange portion 3A via the sleeve 41. The cooling fin 4 and the sleeve 41 are formed from, for example, copper, a copper alloy, aluminum, or an aluminum alloy. The cooling fin 4 and the sleeve 41 may be formed of materials other than those described above.

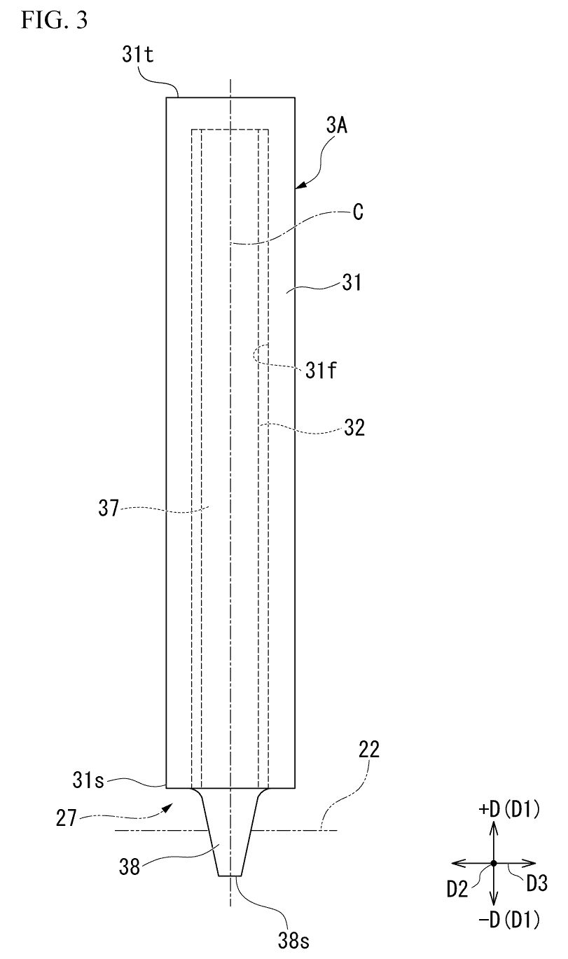

FIG. 3 is a view of the heat exchange portion 3A when viewed from the second direction D2. As shown in FIGS. 1 and 3, in the heat transfer element lA, each of the heat exchange portions 3A includes a container protruding portion 38. The container protruding portion 38 is formed in a part of the peripheral direction (i.e., a partial periphery of the second container 31 along the peripheral direction) around the central axis of the second container 31. The partial periphery of the second container 31 where the container protruding portion 38 is formed may be, for example, in a range of 1/6 to 1/3 of the full periphery of the second container 31 along the peripheral direction. In one or more embodiments of the present disclosure, the partial periphery of the second container 31 where the container protruding portion 38 is formed may be approximately 1/4 of the entire periphery of the second container 31 along the peripheral direction.

It is noted that as shown in FIG. 3, a width of the container protruding portion 38 in the peripheral direction may decrease toward the -D direction. The present invention is not limited to this example, and the width of the container protruding portion 38 in the peripheral direction may be constant in the entire length in the first direction D1.

As shown in FIG. 1, the container protruding portion 38 protrudes from a lower surface 25b of the upper wall portion 25 toward the -D direction. A tip end portion 38s of the container protruding portion 38 is in contact with the first wick 22 in the storage chamber 27 of the first container 21. The tip end portion 38s of the container protruding portion 38 may be inserted (embedded) into the first wick 22. In addition, the tip end portion 38s of the container protruding portion 38 may pass through the first wick 22 and be in contact with the bottom wall portion 23. In addition, the tip end portion 38s of the container protruding portion 38 may be spaced apart from the first wick 22 as long as the working fluid bulged toward the first wick side from the tip end portion 38s due to the surface tension can be quickly captured.

Next, the operation of the heat transfer element 1A will be described. The heat transfer element 1A is used in a state where the contact surface 23f is in contact with the heat generating body 100. For example, a posture of the first direction D1 of the heat transfer element 1A may match a vertical direction. However, the heat transfer element 1A may be used in a posture in which the first direction D1 is inclined with respect to the vertical direction. The heat transfer element 1A may be disposed in a posture in which the first direction D1 matches the horizontal direction.

In the heat transfer element 1A, the heat generated by the heat generating body 100 is transferred to the liquid working fluid in the storage chamber 27 through the vapor chamber 2. Accordingly, in a case where the working fluid is heated to a saturation temperature or higher and vaporized, the vapor flows from the storage chamber 27 into the inner space 37 in the heat exchange portion 3A. The heat of the working fluid that has flowed into the inner space 37 is transferred to the cooling fins 4 via the heat exchange portion 3A. The heat of the working fluid transferred to the cooling fins 4 is dissipated to the atmosphere around the cooling fins 4. Accordingly, in a case where the temperature of the working fluid in the inner space 37 is decreased and the working fluid is condensed, the liquid working fluid is captured by the second wick 32 provided in the second container 31 of the heat exchange portion 3A, passes through the second wick 32, and returns to the first wick 22 in the storage chamber 27 of the vapor chamber 2. In this case, in the first end portion 31s of the heat exchange portion 3A, the working fluid that moves through the second wick 32 flows along the surface of the container protruding portion 38 and smoothly moves to the first wick 22 in the storage chamber 27.

The liquid that has returned to the first wick 22 receives heat from the heat generating body 100 again and evaporates. As described above, the heat transfer element 1A can repeatedly transfer the heat of the heat generating body 100 to the cooling fins 4. Therefore, the heat generating body 100 can be cooled.

As described above, the heat transfer element lA of one or more embodiments includes the heat exchange portion 3A extending in the first direction D1 and the vapor chamber 2 that is connected to the first end portion 31s of the heat exchange portion 3A and has the contact surface 23f that comes into contact with the heat generating body 100, in which the vapor chamber 2 includes the first container 21 that communicates with the inner space 37 of the heat exchange portion 3A and forms the storage chamber 27 in which the working fluid is stored, and the first wick 22 that is disposed in the storage chamber 27 and is capable of retaining the working fluid, the heat exchange portion 3A includes the second container 31 that forms the inner space 37, and the second container 31 includes the container protruding portion 38 that protrudes toward the first wick 22 in the storage chamber 27 in a part of a peripheral direction around the central axis C of the second container 31.

With such a configuration, the working fluid condensed in the heat exchange portion 3A moves from the heat exchange portion 3A to the first wick 22 in the storage chamber 27 along the container protruding portion 38. In a case where the container protruding portion 38 is not provided, the liquid may remain in the vicinity of the first end portion 31s of the second container 31 or on the lower surface 25b of the upper wall portion 25, and it may be difficult for the liquid to return to the first wick 22. The presence of the container protruding portion 38 makes it possible to smoothly recover the working fluid condensed in the heat exchange portion 3A to the first wick 22 in the storage chamber 27.

In addition, the tip end portion 38s of the container protruding portion 38 is in contact with the first wick 22. With this configuration, the working fluid condensed in the heat exchange portion 3A is more quickly moved from the container protruding portion 38 to the first wick 22. Therefore, the working fluid condensed in the heat exchange portion 3A can be more smoothly recovered to the first wick 22 in the storage chamber 27.

In addition, the heat transfer element 1A further includes the cooling fins 4 joined to the outer peripheral surface of the heat exchange portion 3A. With this configuration, the heat of the vaporized working fluid can be efficiently dissipated to the surrounding atmosphere through the cooling fins 4.

### Modification Example of First Embodiments

In the first embodiments, the second containers 31 each provides one container protruding portion 38 in a part of the peripheral direction of the second container 31, but the present invention is not limited thereto.

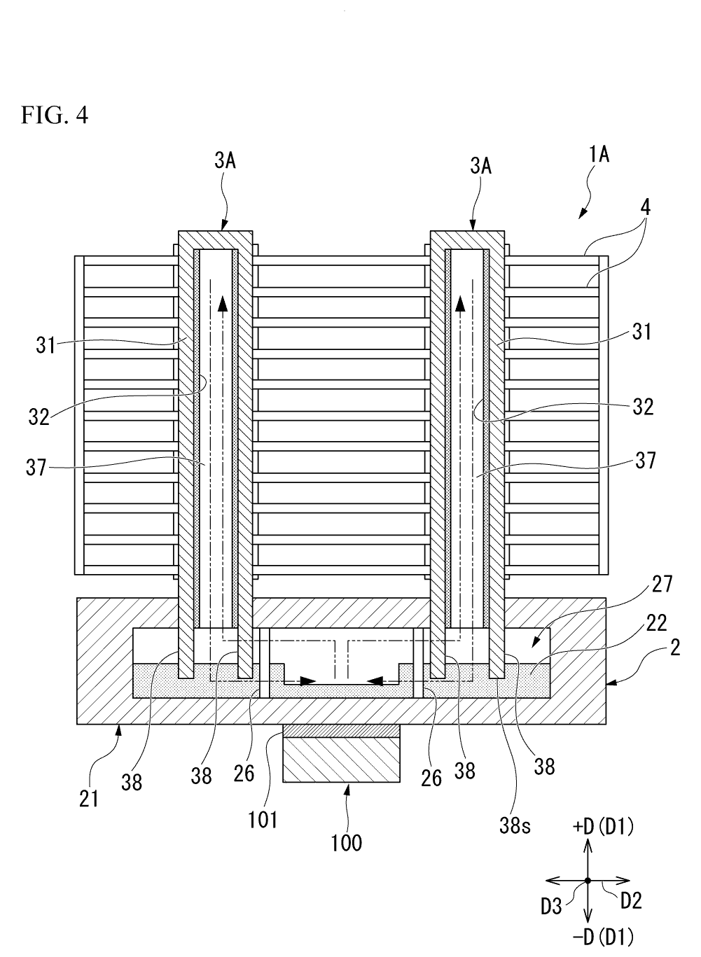

For example, as shown in FIG. 4, a plurality of the container protruding portions 38 may be provided at intervals in the peripheral direction of the second container 31. In the present modification example, for example, two container protruding portions 38 are provided at intervals in the peripheral direction of the second container 31.

With this configuration, the working fluid condensed in the heat exchange portion 3A is more quickly moved from the plurality of container protruding portions 38 to the first wick 22.

### Second Embodiments

Next, the heat transfer element according to second embodiments of the present invention will be described, but the basic configuration is the same as that of the first embodiments. Therefore, the same configurations are denoted by the same reference signs, a description thereof will be omitted, and only differences will be described.

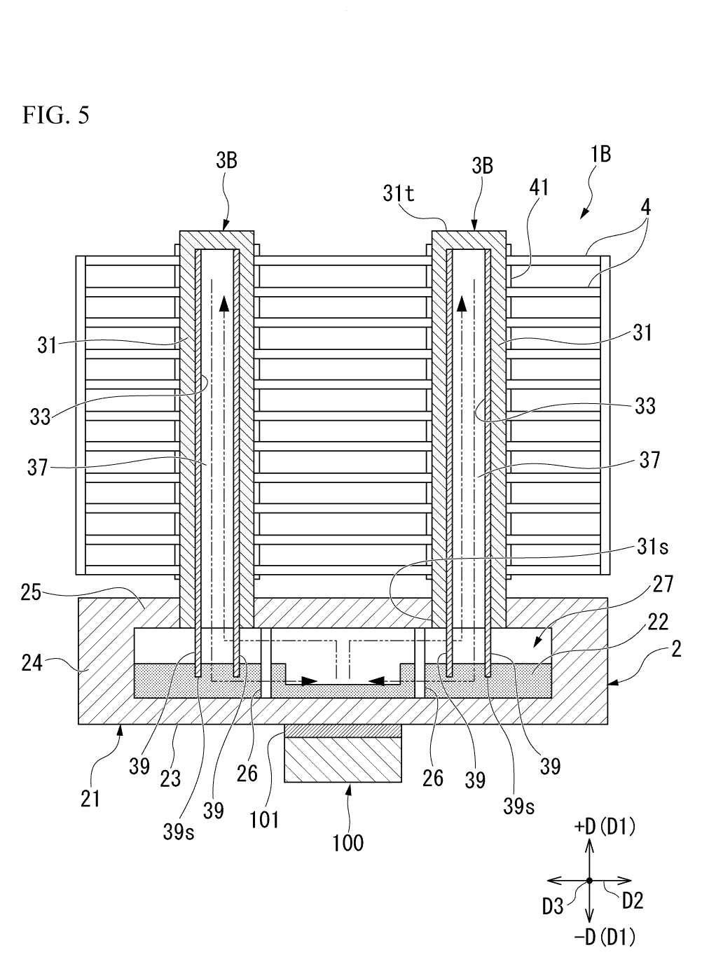

FIG. 5 is a cross-sectional view showing a heat transfer element 1B according to the second embodiments. As shown in FIG. 5, the heat transfer element 1B includes a vapor chamber 2, a heat exchange portion 3B, and a cooling fin 4.

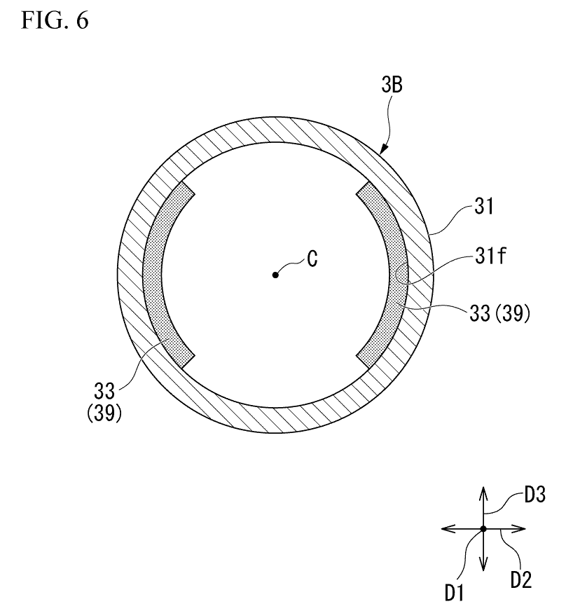

FIG. 6 is a cross-sectional view of the heat exchange portion of the heat transfer element according to the second embodiments when viewed from the first direction. As shown in FIGS. 5 and 6, in one or more embodiments, the heat exchange portion 3B includes the cylindrical second container 31 and a second wick 33. The second wick 33 is disposed along the inner peripheral surface 31f of the second container 31 in the second container 31. For example, two second wicks 33 are provided on the inner peripheral surface 31f of the second container 31 at intervals in the peripheral direction of the second container 31. The second wick 33 extends in the first direction D1 along the inner peripheral surface 31 f of the second container 31.

The second wick 33 is formed from a powder wick consisting of a sintered porous body of a metal powder such as copper, a wire wick which is a braided body consisting of a plurality of metal wires such as copper, and the like. The second wick 33 is capable of capturing and retaining the working fluid condensed in the second container 31 by a capillary force in the second container 31.

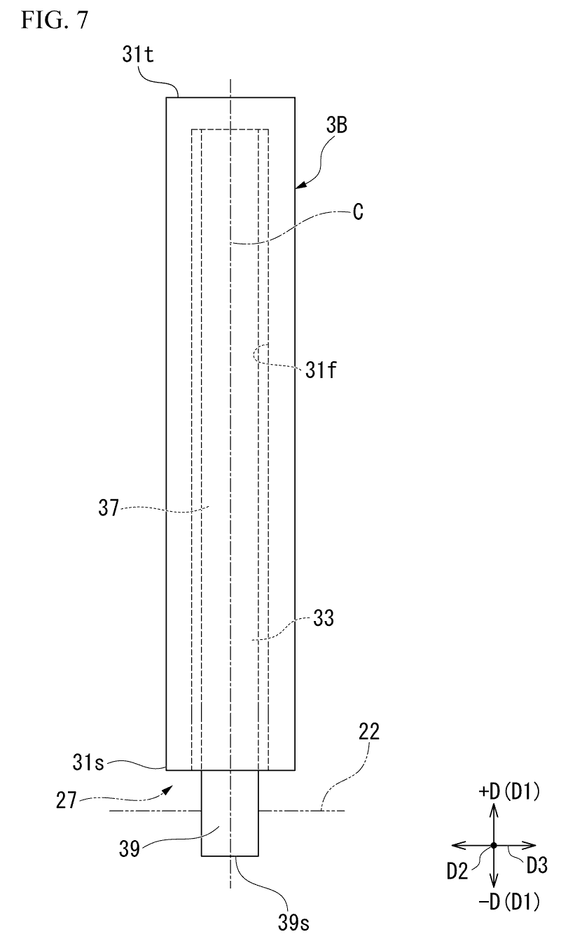

FIG. 7 is a view of the heat exchange portion of FIG. 6 when viewed from the second direction. As shown in FIGS. 5 and 7, in the heat transfer element 1B as described above, each heat exchange portion 3B includes a wick protruding portion 39. The wick protruding portion 39 is formed in a part of the peripheral direction (i.e., a partial periphery of the second wick 33 along the peripheral direction) around the central axis C in the heat exchange portion 3B. The wick protruding portion 39 is continuously provided in each of the two second wicks 33 disposed at intervals in the peripheral direction in the second container 31. The partial periphery of the second wick 33 where each of the wick protruding portions 39 is formed may be, for example, in a range of 1/6 to 1/3 of the full periphery of the second wick 33 along the peripheral direction of the heat exchange portion 3B. In one or more embodiments of the present disclosure, the partial periphery of the second wick 33 where the wick protruding portion 39 is formed may be, for example, approximately 1/4 of the full periphery of the second wick 33 along the peripheral direction of the heat exchange portion 3B.

It is noted that as shown in FIG. 7, the width of the wick protruding portion 39 in the peripheral direction may be constant in the entire length in the first direction D1. The present invention is not limited to this example, and the width of the wick protruding portion 39 in the peripheral direction may decrease toward the -D direction.

The wick protruding portion 39 protrudes from the first end portion 31s of the second container 31 toward the -D direction. The tip end portion 39s of the wick protruding portion 39 is in contact with the first wick 22 in the storage chamber 27 of the first container 21. The tip end portion 39s of the wick protruding portion 39 may be inserted (embedded) into the first wick 22. In addition, the tip end portion 39s of the wick protruding portion 39 may pass through the first wick 22 and be in contact with the bottom wall portion 23. In addition, the tip end portion 39s of the wick protruding portion 39 may be spaced apart from the first wick 22 as long as the working fluid bulged from the tip end portion 39s to the first wick side due to the surface tension can be quickly captured.

In such a heat transfer element 1B, the working fluid condensed in the heat exchange portion 3B is captured by the second wick 33 provided in the second container 31, and returns to the storage chamber 27 of the vapor chamber 2 through the second wick 33. In this case, in the first end portion 31s of the heat exchange portion 3B, the working fluid that moves through the second wick 33 flows along the surface of the wick protruding portion 39 and smoothly moves to the first wick 22 in the storage chamber 27.

As described above, the heat transfer element 1B of one or more embodiments includes the heat exchange portion 3B extending in the first direction D1 and the vapor chamber 2 that is connected to the first end portion 31s of the heat exchange portion 3B and has the contact surface 23f that comes into contact with the heat generating body 100, in which the vapor chamber 2 includes the first container 21 that communicates with the inner space 37 of the heat exchange portion 3B and forms the storage chamber 27 in which the working fluid is stored, and the first wick 22 that is disposed in the storage chamber 27 and is capable of retaining the working fluid, the heat exchange portion 3B includes the second container 31 that forms the inner space 37 and the second wick 33 that is provided in the inner space 37 and is capable of retaining the working fluid, and the second wick 33 includes the wick protruding portion 39 that protrudes toward the first wick 22 in the storage chamber 27 in a part of a peripheral direction around the central axis C of the second container 31.

With such a configuration, the working fluid condensed in the heat exchange portion 3B moves from the heat exchange portion 3B to the first wick 22 in the storage chamber 27 along the wick protruding portion 39. Therefore, the working fluid condensed in the heat exchange portion 3B can be smoothly recovered to the first wick 22 in the storage chamber 27.

In addition, the tip end portion 39s of the wick protruding portion 39 is in contact with the first wick 22. With this configuration, the working fluid condensed in the heat exchange portion 3B moves from the wick protruding portion 39 to the first wick 22 more quickly. Therefore, the working fluid condensed in the heat exchange portion 3B can be more smoothly recovered to the first wick 22 in the storage chamber 27.

In addition, the plurality of second wicks 33 are provided on the inner peripheral surface of the second container 31 at intervals in the peripheral direction, and each of the second wicks 33 extends in the first direction D1. With this configuration, the working fluid condensed in the heat exchange portion 3B can be smoothly moved to the wick protruding portion 39 through the second wick 33 extending in the first direction D1 in the heat exchange portion 3B.

In addition, the plurality of wick protruding portions 39 are provided at intervals in the peripheral direction in the inner peripheral surface of the second container 31. As a result, the working fluid condensed in the heat exchange portion 3B can be more smoothly moved to the first wick 22 in the storage chamber 27 through the plurality of wick protruding portions 39.

### Modification Example of Second Embodiments

In the second embodiments, for example, two second wicks 33 are provided at intervals in the peripheral direction of the second container 31, but the present invention is not limited thereto. For example, as shown in FIGS. 2 and 3, the second wick 33 may be provided over the entire periphery of the second container 31 in the peripheral direction. In this case, the two wick protruding portions 39 at intervals in the peripheral direction may be provided to protrude from the second wick 33 toward the -D direction.

Even in this configuration, the working fluid condensed in the heat exchange portion 3B is more quickly moved from the plurality of (two) wick protruding portions 39 to the first wick 22.

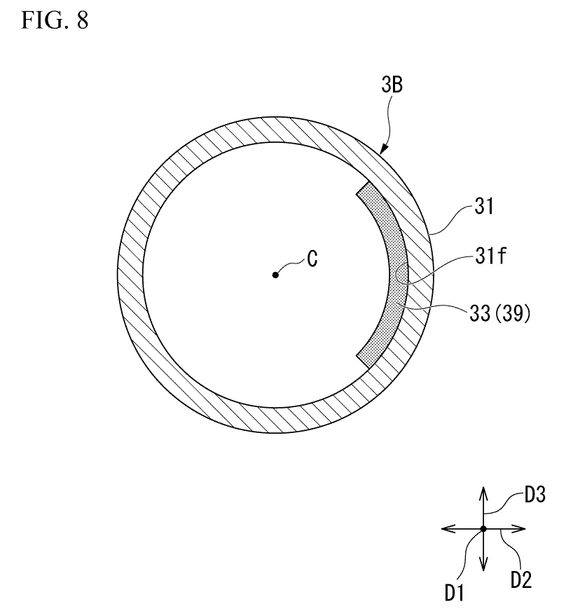

In addition, as shown in FIG. 8, the second wick 33 may be provided at only one position in the peripheral direction of the second container 31. In this case, the wick protruding portion 39 is also provided only at one position in the peripheral direction of the second container 31.

Even in this configuration, the working fluid condensed in the heat exchange portion 3B moves more quickly from the wick protruding portion 39 to the first wick 22.

It is noted that a technical scope of the present invention is not limited to the above- described embodiments, and various modifications can be made without departing from the scope of the present invention.

For example, in the first embodiments, the container protruding portion 38 is provided in the second container 31, and in the second embodiments, the wick protruding portion 39 is provided in the second wick 33. However, both the container protruding portion 38 provided in the second container 31 and the wick protruding portion 39 provided in the second wick 33 can be provided.

In addition, within the scope not departing from the concept of the present invention, configuration elements in the above-described embodiments can be appropriately replaced with well-known configuration elements, and the above-described embodiments or modification examples may be appropriately combined.

### Examination Example

The heat transfer elements lA and 1B shown in the first and second embodiments and the modification examples thereof were examined, and the results are shown below.

As objects to be examined, heat transfer elements including heat pipes of the following Examples 1 to 4 and Comparative Example were prepared.

Example 1: Heat Pipe (Corresponding to Configuration in FIGS. 1 to 3) Including Container Protruding Portion in Second Container

Example 2: Heat Pipe (Corresponding to Configuration in FIG. 8) Including Second Wick and Wick Protruding Portion at One Position in Peripheral Direction of Second Container

Example 3: Heat Pipe (Corresponding to Configuration in FIGS. 5 to 7) in Which Second Wick is Provided on Entire Periphery of Second Container in Peripheral Direction and Wick Protruding Portions are Provided at Two Positions in Peripheral Direction

Comparative Example: Heat Pipe not Provided with Container Protruding Portion and Wick Protruding Portion

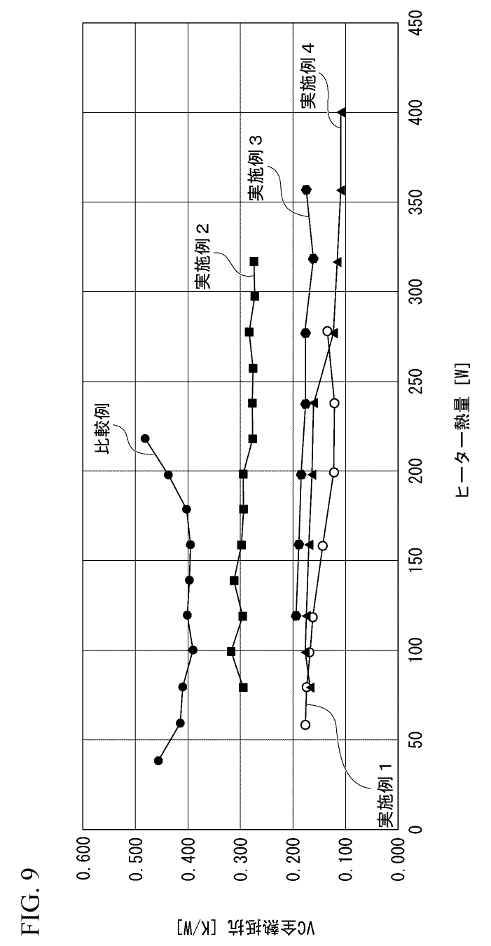

For each of Examples 1 to 4 and Comparative Example as described above, the heat amount of a heater corresponding to the heat generating body was changed, and a total thermal resistance in the vapor chamber (VC) was measured. The results are shown in FIG. 9. As shown in FIG. 9, it was confirmed that the total thermal resistance was low in any of Examples 1 to 4 as compared with the comparative example. In addition, it was confirmed that the total thermal resistance was particularly low in Examples 1 and 4 among Examples 1 to 4. Accordingly, it can be presumed that the total thermal resistance in the vapor chamber is suppressed by smoothly recovering the working fluid condensed in the heat pipe in the wick (first wick) in the storage chamber of the vapor chamber.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1A, 1B: Heat transfer element

2: Vapor chamber

3A, 3B: Heat exchange portion (heat pipe)

4: Cooling fin

21: First container

22: First wick

23f: Contact surface 27: Storage chamber 31: Second container

31 f: Inner peripheral surface

31s: First end portion 32, 33: Second wick

37: Inner space

38: Container protruding portion

38s: Tip end portion

39: Wick protruding portion

39s: Tip end portion

100: Heat generating body

1. A heat transfer element comprising: a heat exchange portion and a vapor chamber connected to an end of the heat exchange portion and that has a contact surface that contacts a heat generating body, wherein the vapor chamber comprises: a first container that communicates with an inner space of the heat exchange portion and forms a storage chamber in which a working fluid is stored; and a wick is disposed in the storage chamber and configured to retain the working fluid,
the heat exchange portion comprises a second container that forms the inner space, the second container comprises a container protruding portion that protrudes into the storage chamber toward the wick, and the container protruding portion is formed on a partial periphery of the second container along a peripheral direction around a central axis of the second container.

2. The heat transfer element according to claim 1, wherein a tip end of the container protruding portion contacts the wick.

3. The heat transfer element according to claim 1, wherein the second containerfurther comprises one or more additional container protruding portions andall of thecontainer protruding portions aredisposed at intervals in the peripheral direction.

4. A heat transfer element comprising: a heat exchange portion that extends in a first direction; and
a vapor chamber connected to an end of the heat exchange portion and that has a contact surface that contacts a heat generating body, wherein the vapor chamber comprises: a first container that communicates with an inner space of the heat exchange portion and forms a storage chamber in which a working fluid is stored; and a first wick-that-s disposed in the storage chamber and configured to retain the working fluid,
the heat exchange portion-comprises: a second container that forms the inner space, and a second wick disposed in the inner space and configured to retain the working fluid, the second wick comprises a wick protruding portion that protrudes into the storage chamber toward the first wick, and the wick protruding portion is formed on a partial periphery of the second wick along a peripheral direction around a central axis of the second container.

5. The heat transfer element according to claim 4, wherein a tip end of the wick protruding portiocontacts the first wick.

6. The heat transfer element according to claim 4, wherein the second wick is disposed in a part of an inner peripheral surface of the second container in the peripheral direction and extends in the first direction.

7. The heat transfer element according to claim 6, wherein the heat exchange portion further comprises one or more additional second wicks and all of the second wicks are disposed on the inner peripheral surface of the second container at intervals in the peripheral direction.

8. The heat transfer element according to claim 4, wherein the second wick isdisposed over an entire periphery of an inner peripheral surface of the second container in the peripheral directionand extends in the first direction.

9. The heat transfer element according to claim 4, wherein the second wickfurther comprises one or more additional wick protruding portions,andall of thewick protruding portions aredisposed on an inner peripheral surface of the second container at intervals in the peripheral direction.

10. The heat transfer element according to claim 1, further comprising a cooling fin that is joined to an outer peripheral surface of the heat exchange portion.

11. The heat transfer element according to claim 4, further comprising: a cooling fin that is joined to an outer peripheral surface of the heat exchange portion.
